(19) United States
(12) Patent Application Publication
(10) Pub. No.: US 2026/0107770 A1
(43) Pub. Date: Apr. 16, 2026

(54) SEMICONDUCTOR PACKAGE

(71) Applicant: Samsung Electronics Co., Ltd., Suwon-si (KR)

(72) Inventors: Eunbeom Jeon, Suwon-si (KR); Sangwoo Park, Suwon-si (KR)

(21) Appl. No.: 19/209,991

(22) Filed: May 16, 2025

(30) Foreign Application Priority Data
Oct. 10, 2024 (KR) 10-2024-0137659

(51) Int. Cl. H01L 23/367; H01L 21/56; H01L 23/00; H01L 23/31; H01L 25/065; H05K 1/18

(52) U.S. Cl. CPC H10W 40/228; H10W 74/114; H05K 1/181; H10W 72/0198; H10W 72/5445; H10W 72/865; H10W 72/884; H10W 72/9445; H10W 72/965; H10W 72/967; H10W 74/016; H10W 74/10; H10W 90/00; H10W 90/20; H10W 90/24; H10W 90/288; H10W 90/732; H10W 90/734; H10W 90/752; H10W 90/754

(57) ABSTRACT

A semiconductor package according to an embodiment of the present disclosure includes: a substrate; a semiconductor chip on the substrate and electrically connected to the substrate; at least one heat dissipation wire connected to the semiconductor chip; and an encapsulant on at least a portion of each of the semiconductor chip and the heat dissipation wire. The heat dissipation wire is exposed to one side surface of side surfaces of the encapsulant.

### CROSS-REFERENCE TO RELATED APPLICATION

This application claims priority to and the benefit of Korean Patent Application No. 10-2024-0137659, filed on Oct. 10, 2024, at the Korean Intellectual Property Office, the entire contents of which are incorporated herein by reference.

### TECHNICAL FIELD

The present disclosure relates to a semiconductor package.

### BACKGROUND OF THE INVENTION

As an electronic product becomes miniaturized, high-performance, multi-functional, and large-capacity, an importance of a thermal characteristic of a semiconductor package is increasing. If a high-temperature heat generated in the semiconductor package is not effectively dissipated to the outside, problems such as product performance degradation, reliability deterioration, and lifespan degradation may occur.

### SUMMARY OF THE INVENTION

An aspect of the present disclosure is intended to provide a semiconductor package with an improved heat dissipation characteristic.

A semiconductor package according to an embodiment of the present disclosure includes: a substrate; a semiconductor chip on the substrate and electrically connected to the substrate; at least one heat dissipation wire connected to the semiconductor chip; and an encapsulant on at least a portion of each of the semiconductor chip and the heat dissipation wire. The heat dissipation wire is exposed to one side surface of side surfaces of the encapsulant.

A semiconductor package according to another embodiment of the present disclosure includes: a substrate; a plurality of semiconductor chips on the substrate; bonding wires electrically connecting each of the plurality of semiconductor chips to the substrate; at least one heat dissipation wire connected to at least one of the plurality of semiconductor chips; and an encapsulant on at least a portion of each of the plurality of semiconductor chips, the bonding wires, and the heat dissipation wire. The heat dissipation wire is exposed to one side surface of side surfaces of the encapsulant.

A semiconductor package according to another embodiment of the present disclosure includes: a substrate; a first semiconductor chip on the substrate; a second semiconductor chip spaced apart from the first semiconductor chip and on the substrate; first bonding wires that electrically connect the first semiconductor chip and the substrate; second bonding wires that electrically connect the second semiconductor chip and the substrate; a first heat dissipation wire connected to the first semiconductor chip; a second heat dissipation wire connected to the second semiconductor chip; and an encapsulant on at least a portion of each of the semiconductor chip, the first bonding wires, the second bonding wires, the first heat dissipation wire, and the second heat dissipation wire. Each of the first heat dissipation wire and the second heat dissipation wire is exposed to one side surface of side surfaces of the encapsulant.

The aspect of the present disclosure may provide a semiconductor package with an improved heat dissipation characteristic.

### BRIEF DESCRIPTION OF THE DRAWINGS

FIG. 1 is a cross-sectional view of a semiconductor package according to embodiments.

FIG. 2 is a schematic cross-sectional view of a semiconductor chip.

FIG. 3 is a plan view of the semiconductor package of FIG. 1.

FIG. 4 is a plan view according to a modified example of the semiconductor package of FIG. 1.

FIG. 5 is a plan view according to another modified example of the semiconductor package of FIG. 1.

FIG. 6 is a cross-sectional view of a semiconductor package according to another embodiment.

FIG. 7 is a plan view of the semiconductor package of FIG. 6.

Each of FIG. 8 and FIG. 9 is a cross-sectional view of a semiconductor package according to another embodiment.

FIG. 10 is a plan view of the semiconductor package of FIG. 8.

FIG. 11 is a plan view according to a modified example of the semiconductor package of FIG. 7.

FIG. 12 is a cross-sectional view of a semiconductor package according to another embodiment.

FIG. 13 is a cross-sectional view of a semiconductor package according to another embodiment.

FIG. 14 is a plan view of the semiconductor package of FIG. 13.

FIG. 15 is a plan view according to a modified example of the semiconductor package of FIG. 13.

FIG. 16 is a plan view according to another modified example of the semiconductor package of FIG. 13.

FIG. 17 is a cross-sectional view of a semiconductor package according to another embodiment.

Each of FIG. 18 and FIG. 19 is a cross-sectional view of a semiconductor package according to another embodiment.

FIGS. 20 to 24 are manufacturing process views of the semiconductor package of FIG. 6.

### DETAILED DESCRIPTION OF THE EMBODIMENTS

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

To clearly describe the present disclosure, parts or portions that are irrelevant to the description are omitted, and identical or similar constituent elements throughout the specification are denoted by the same reference numerals.

In the drawings, each element's size and thickness are arbitrarily illustrated for ease of description, but the present disclosure is not necessarily limited to those illustrated in the drawings. In the drawings, the thicknesses of some layers and areas are exaggerated for clarity. In the drawings, for ease of description, the thicknesses of some layers and areas are exaggerated.

Throughout the specification, when a part is “connected” to another part, it includes not only a case where the part is “directly connected” but also a case where the part is “indirectly connected” with another part in between. In a similar sense, this includes being “physically connected”as well as being “electrically connected”.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

In addition, throughout the specification, sequential numbers such as 1st and 2nd are used to distinguish a certain component from another component that is the same as or similar to the certain component and are not necessarily intended to refer to a specific component. Accordingly, a component referred to as a first component in a specific portion of the specification may be referred to as a second component in another portion of the specification.

Throughout the specification, references to directions such as “upper surface”, “upper side”, “upper portion”, “lower surface”, “lower side”, and “lower portion” are described to help understanding based on the drawings.

The term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

Hereinafter, a semiconductor package according to embodiments of the present disclosure will be described with reference to the drawings.

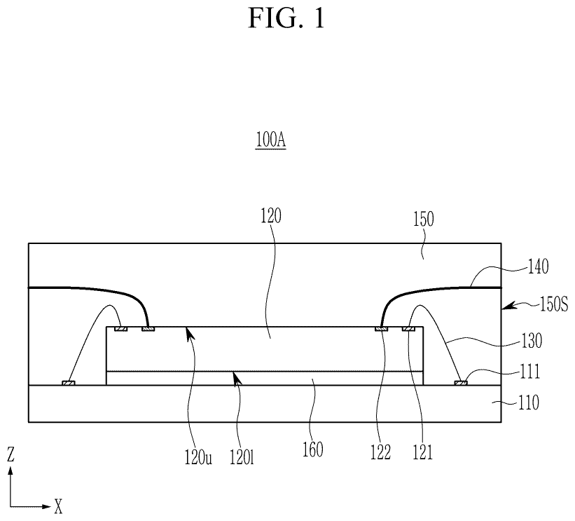

FIG. 1 is a cross-sectional view of the semiconductor package according to an embodiment.

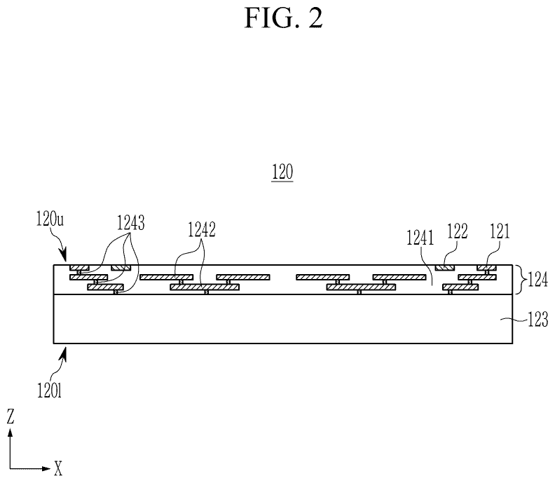

FIG. 2 is a schematic cross-sectional view of a semiconductor chip.

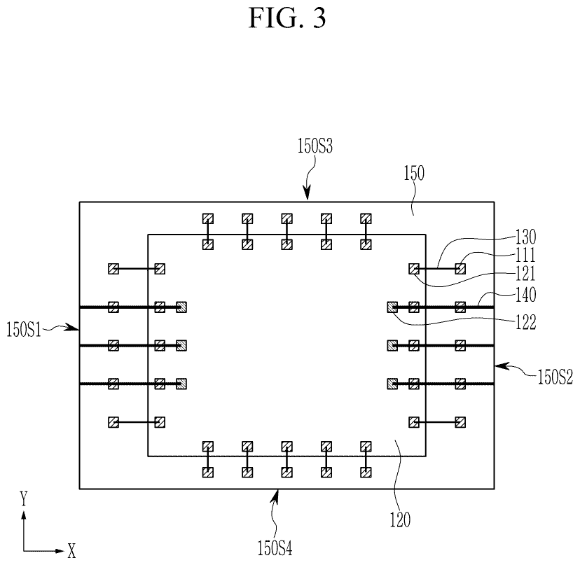

FIG. 3 is a plan view of the semiconductor package of FIG. 1.

The semiconductor package 100A may include a substrate 110, the semiconductor chip 120, bonding wire(s) 130, heat dissipation wire(s) 140, and an encapsulant (or a sealant) 150.

To clearly show a layout of the substrate 110, the semiconductor chip 120, the bonding wire 130, and the heat dissipation wire 140, the encapsulant 150 is assumed to be transparent in each of the drawings.

The substrate 110 may be a printed circuit board (PCB) and may include pads 111 for electrical connection between the substrate 110 and the semiconductor chip 120. A disposition form of the pads 111 is not particularly limited. For example, the pads 111 may be disposed to surround the semiconductor chip 120 on a plane or may be disposed at both sides of the semiconductor chip 120. A conductive material such as copper (Cu) or aluminum (Al) may be used as a material of the pad 111.

The semiconductor chip 120 may be disposed above the substrate 110 to be electrically connected to the substrate 110. The semiconductor chip 120 may be connected to the substrate 110 by wire bonding but may also be connected to the substrate 110 through another bonding method such as flip-chip bonding if necessary.

The semiconductor chip 120 may include a connection pad 121, a heat dissipation pad 122, a semiconductor substrate 123, and a wiring structure 124, and may have an upper surface 120u on which the connection pad 121 and the heat dissipation pad 122 are disposed and a lower surface 120l on which the semiconductor substrate 123 is disposed.

The semiconductor chip 120 may be disposed above the substrate 110 so that the lower surface 120l faces the substrate 110.

The connection pad 121 may be electrically connected to the wiring structure 124 to perform a function such as signal transfer, power transfer, or ground. For example, the connection pad 121 may be connected to a wiring layer 1242 through a via 1243 of the wiring structure 124. The connection pad 121 may be disposed along an area adjacent to an edge of the semiconductor chip 120, but the present disclosure is not limited thereto.

The heat dissipation pad 122 may not be electrically connected to the wiring structure 124. However, according to an embodiment, the heat dissipation pad 122 may be connected to the wiring structure 124 (e.g., a ground wire). The heat dissipation pad 122 may be disposed at an area other than an area where connection pads 121 are disposed (e.g., an area farther from an edge of the semiconductor chip 120 than the connection pad 121), but the present disclosure is not limited thereto.

The semiconductor substrate 123 may include a semiconductor element such as silicon (Si) or germanium (Ge), or a compound semiconductor such as gallium arsenide (GaAs) or indium arsenide (InAs).

The wiring structure 124 may be disposed on the semiconductor substrate 123, and may include an interlayer insulating layer 1241, the wiring layer 1242, and the via 1243. A plurality of individual elements (e.g., transistors) may be formed between the semiconductor substrate 123 and the wiring structure 124.

The semiconductor chip 120 may further include a passivation film disposed on the wiring structure 124 to expose at least a portion of each of the connection pad 121 and the heat dissipation pad 122.

An adhesive member 160 may be interposed between the semiconductor chip 120 and the substrate 110 to adhere the semiconductor chip 120 and the substrate 110 to each other. A material having adherence and insulation properties such as a die attach film (DAF) may be used as a material of the adhesive member 160.

The bonding wires 130 may be connected to the connection pad 121 of the semiconductor chip 120 to connect the semiconductor chip 120 to the substrate 110. The bonding wires 130 may extend from the connection pad 121 of the semiconductor chip 120 to the pad 111 of the substrate 110.

A diameter of the bonding wire 130 may be about 18μm to 25μm.

A conductive material may be used as a material of the bonding wire 130, and for example, a metal such as copper (Cu), aluminum (Al), or gold (Au) or an alloy of metals may be used.

The heat dissipation wire 140 may be connected to the heat dissipation pad 122 of the semiconductor chip 120 and may be exposed to a side surface 150S of the encapsulant 150. That is, one end of the heat dissipation wire 140 may be connected to the heat dissipation pad 122 of the semiconductor chip 120, and the other end of the heat dissipation wire 140 may be exposed to the side surface 150S of the encapsulant 150. That is, the heat dissipation wire 140 may penetrate the side surface 150S of the encapsulant 150. The term “exposed” (or “exposes,” or like terms) may be used herein to describe relationships between elements and/or with reference to intermediate manufacturing processes, but may not require exposure of the entirety of a particular element in the completed device.

As described below, the heat dissipation wires 140 may be exposed to the side surface 150S of the encapsulant 150 by being cut together with the encapsulant 150 in a cutting process in which individual semiconductor packages are separated.

In an embodiment, the heat dissipation wires 140 may include a heat dissipation wire exposed to a first side surface 150S1 of the encapsulant 150 and a heat dissipation wire exposed to a second side surface 150S2 facing the first side surface 150S1 of the encapsulant 150 in an X direction (X). The heat dissipation wire exposed to the first side surface 150S1 of the encapsulant 150 and the heat dissipation wire exposed to the second side surface 150S2 of the encapsulant 150 may be spaced apart from each other in the X direction (X) (e.g., a direction from the first side surface 150S1 toward the second side surface 150S2). The heat dissipation wires exposed to the first side surface 150S1 of the encapsulant 150 and the heat dissipation wires exposed to the second side surface 150S2 of the encapsulant 150 may be each disposed along a Y direction (Y).

It has been confirmed through simulation that a thermal resistance is reduced by about 19% from 1.19°C/W to 0.96°C/W in a case in which the semiconductor package 100A includes the heat dissipation wires 140 exposed to two side surfaces 150S1 and 150S2 facing each other of the encapsulant 150 compared with a semiconductor package that does not include the heat dissipation wire 140.

However, it may be sufficient for each of the heat dissipation wires 140 to be exposed to one side surface 150S of the encapsulant 150, and the side surfaces 150S to which the heat dissipation wires 140 are exposed may be variously designed. The side surfaces 150S of the encapsulant 150 to which the heat dissipation wires 140 are exposed may be the same or different from each other. For example, the heat dissipation wires 140 may be exposed only to one side surface 150S of the encapsulant 150 (e.g., the first side surface 150S1).

A diameter of the heat dissipation wire 140 may be greater than or equal to the diameter of the bonding wire 130. While the bonding wire 130 requires a fine or thin diameter for electrical performance and high-density packaging, the heat dissipation wire 140 may have a thick diameter to provide an excellent heat dissipation characteristic. The diameter of the heat dissipation wire 140 may be larger than the diameter of the bonding wire 130. For example, the diameter of the heat dissipation wire 140 may be about 18 μm or more, about 18 μm to 100 μm, or about 30 μm to 100 μm.

Like the bonding wire 130, a conductive material may be used as a material of the heat dissipation wire 140, and for example, a metal such as copper (Cu), aluminum (Al), or gold (Au) or an alloy of metals may be used as the material of the heat dissipation wire 140.

The side surfaces 150S of the encapsulant 150 may include the first side surface 150S1 and the second side surface 150S2 facing each other in the X direction (X), and a third side surface 150S3 and a fourth side surface 150S4 connecting the first side surface 150S1 and the second side surface 150S2 and facing each other in the Y direction (Y).

An insulating material such as an epoxy molding compound (EMC) may be used as a material of the encapsulant 150.

According to embodiments of the present disclosure, the heat dissipation wire 140 may be exposed to the side surface 150S of the encapsulant 150, so that heat generated from the semiconductor chip 120 is efficiently dissipated to the outside of the semiconductor package. The heat dissipation wire 140 may be formed through the same wire bonding process as that of the bonding wire 130 and may be exposed to the side surface 150S of the encapsulant 150 through the cutting process, so that it improves a heat dissipation characteristic of the semiconductor package without significantly increasing a process time and a cost. In addition, it may prevent a thickness limitation of a package that is a problem that occurs when a heat sink is attached on the semiconductor package.

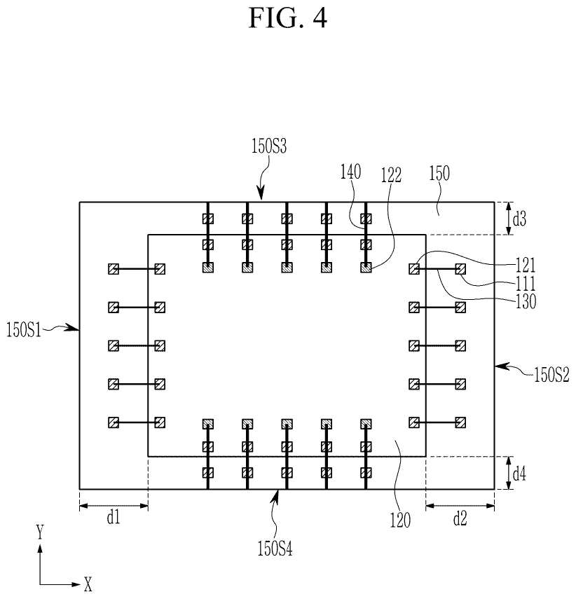

FIG. 4 is a plan view according to a modified example of the semiconductor package of FIG. 1.

Each of the heat dissipation wires 140 may be exposed to a side surface (e.g., the third side surface 150S3 or the fourth side surface 150S4) of the encapsulant 150 having a narrow interval with the semiconductor chip 120. That is, a distance d3 from the third side surface 150S3 of the encapsulant 150 to the semiconductor chip 120 and a distance d4 from the fourth side surface 150S4 of the encapsulant 150 to the semiconductor chip 120 may be lower than a distance d1 from the first side surface 150S1 of the encapsulant 150 to the semiconductor chip 120 and a distance d2 from the second side surface 150S2 of the encapsulant 150 to the semiconductor chip 120. In the present disclosure, a distance between components may mean a shortest distance between the components.

If the distances d3 and d4 between the semiconductor chip 120 and the third side surface 150S3 and the fourth side surface 150S4 of the encapsulant 150 are narrow, the bonding wires 130 may extend from the semiconductor chip 120 to both sides in the X direction (X), and there may be no bonding wires extending to both sides in the Y direction (Y). Even in this case, the heat dissipation wires 140 may be exposed to the third side surface 150S3 and the fourth side surface 150S4 of the encapsulant 150.

Because each of the heat dissipation wires 140 are exposed to a side surface of the encapsulant 150 having a narrow interval with the semiconductor chip 120, a heat dissipation path may be shortened and heat accumulation in the encapsulant 150 may be reduced so that the heat dissipation characteristic of the semiconductor package is further improved. In addition, a narrow space that is difficult to use for a separate use (e.g., a disposition area of the bonding wire 130) of the semiconductor package may be utilized as a heat dissipation path.

In addition to the above description, a description of another portion of the present specification may be equally applied to descriptions of other components unless there is a particularly contradictory description.

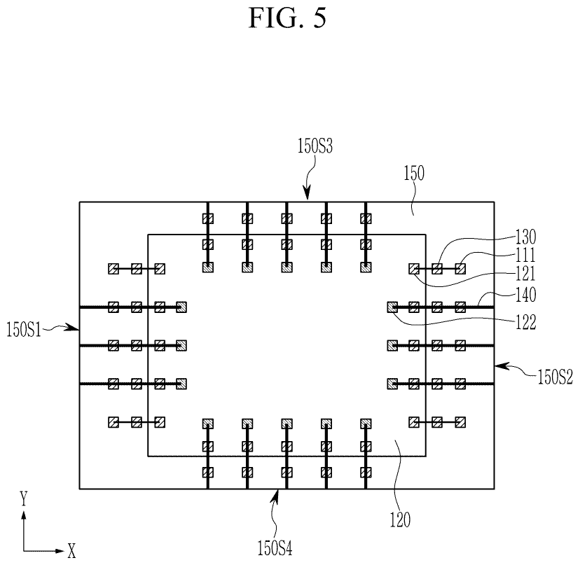

FIG. 5 is a plan view according to another modified example of the semiconductor package of FIG. 1.

The heat dissipation wire 140 may further include a heat dissipation wire exposed to the third side surface 150S3 of the encapsulant 150 and a heat dissipation wire exposed to the fourth side surface 150S4 of the encapsulant 150.

It has been confirmed through simulation that a thermal resistance is reduced by about 28% from 1.19°C./W to 0.86°C./W in a case in which the semiconductor package includes the heat dissipation wires 140 exposed to four side surfaces 150S1, 150S2, 150S3, and 150S4 of the encapsulant 150 compared with a semiconductor package that does not include the heat dissipation wire 140. That is, the case in which the heat dissipation wires 140 are exposed to four side surfaces of the encapsulant 150 may provide the semiconductor package having a better heat dissipation characteristic compared with a case in which the heat dissipation wires are exposed to two side surfaces.

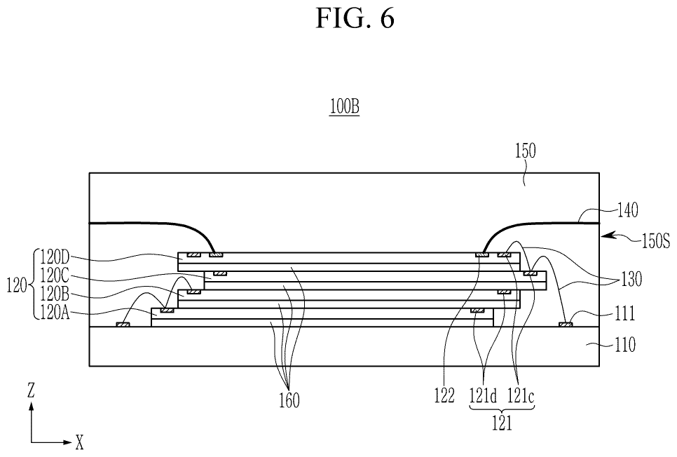

FIG. 6 is a cross-sectional view of a semiconductor package according to another embodiment.

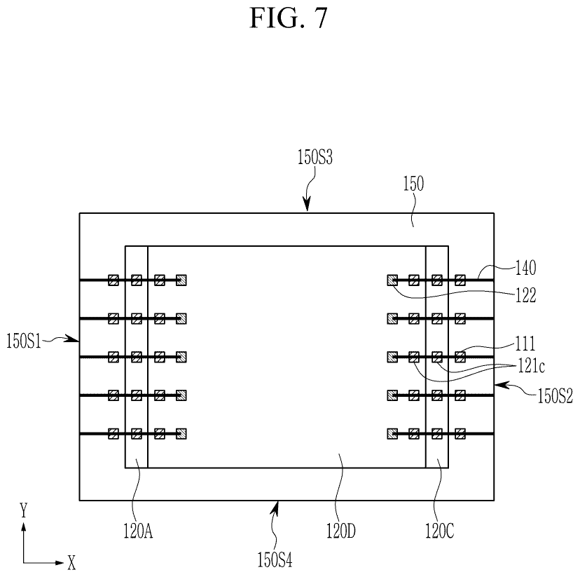

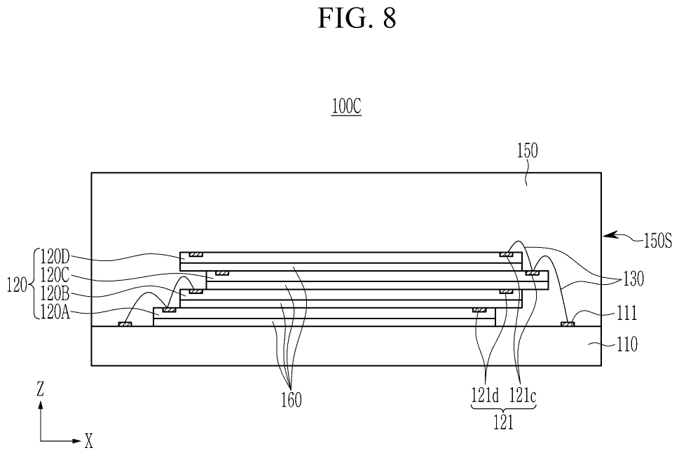

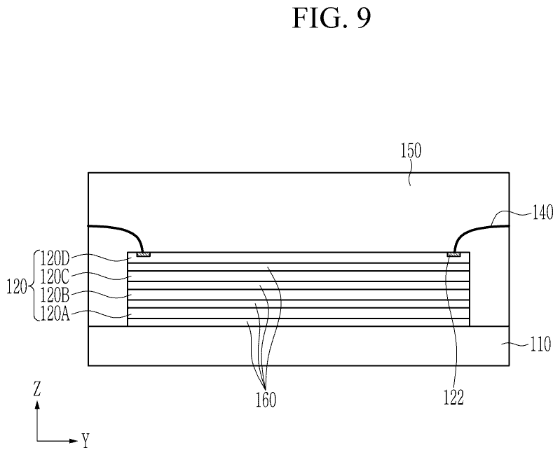

FIG. 7 is a plan view of the semiconductor package of FIG. 6.

A semiconductor chip 120 of the semiconductor package 100B may include a plurality of semiconductor chips stacked along a Z direction (Z) above a substrate 110. For example, the semiconductor chips 120 may include a first semiconductor chip 120A, a second semiconductor chip 120B, a third semiconductor chip 120C, and a fourth semiconductor chip 120D that are sequentially stacked.

Each semiconductor chip 120 may include a first connection pad 121c and a second connection pad 121d each disposed at both edge areas in the X direction (X). The first connection pad 121c may be an actual connection pad connected to a bonding wire 130, and the second connection pad 121d may be a dummy pad not connected to the bonding wire 130. However, the semiconductor chip 120 may include only the first connection pad 121c and may not include the second connection pad 121d that is the dummy pad.

The semiconductor chips 120A, 120B, 120C, and 120D may be stacked to be misaligned with each other in the X direction (X) so that each first connection pad 121c is not covered by another semiconductor chip. The second connection pad 121d of each of the semiconductor chips 120 may be covered by another semiconductor chip disposed above the semiconductor chip 120.

The heat dissipation wire 140 may be connected to at least one of the semiconductor chips 120A, 120B, 120C, and 120D. For example, the heat dissipation wire 140 may be connected to an uppermost semiconductor chip 120D among the semiconductor chips 120A, 120B, 120C, and 120D. Heat from the semiconductor chips 120A, 120B, 120C, and 120D may be transferred upward, and connecting the heat dissipation wire 140 to the uppermost semiconductor chip 120D may be advantageous in terms of a heat dissipation characteristic. However, the semiconductor chip 120 to which the heat dissipation wire 140 is connected may be changed, and for example, the heat dissipation wire 140 may be connected to another semiconductor chip 120A, 120B, or 120C or other semiconductor chips 120A, 120B, and 120C, or the heat dissipation wire 140 may be connected to all semiconductor chips 120A, 120B, 120C, and 120D.

In an embodiment, heat dissipation wires 140 may include a heat dissipation wire exposed to a first side surface 150S1 of an encapsulant 150 and a heat dissipation wire exposed to a second side surface 150S2 of the encapsulant 150 facing the first side surface 150S1 in the X direction (X).

Bonding wires 130 may electrically connect each of the semiconductor chips 120A, 120B, 120C, and 120D to the substrate 110. The bonding wires 130 may extend in the same direction as those of the heat dissipation wires 140 to be connected to the substrate 110. For example, the bonding wires 130 may include a bonding wire (e.g., a bonding wire connected to the first semiconductor chip 120A in the drawings) extending toward the first side surface 150S1 of the encapsulant 150 to be connected to the substrate 110 between the first side surface 150S1 of the encapsulant 150 and the semiconductor chips 120A, 120B, 120C, and 120D and a bonding wire (e.g., a bonding wire connected to the third semiconductor chip 120C in the drawings) extending toward the second side surface 150S2 of the encapsulant 150 to be connected to the substrate 110 between the second side surface 150S2 of the encapsulant 150 and the semiconductor chips 120A, 120B, 120C, and 120D.

In an embodiment, the bonding wires 130 may include bonding wire(s) (e.g., a bonding wire connected to the second semiconductor chip 120B and a bonding wire connected to the fourth semiconductor chip 120D in the drawings) connecting one among the semiconductor chips 120A, 120B, 120C, and 120D to the other among the semiconductor chips 120A, 120B, 120C, and 120D.

For example, the bonding wires 130 may include a bonding wire connecting the first semiconductor chip 120A to the substrate 110, a bonding wire connecting the second semiconductor chip 120B to the first semiconductor chip 120A, a bonding wire connecting the third semiconductor chip 120C to the substrate 110, and a bonding wire connecting the fourth semiconductor chip 120D to the third semiconductor chip 120C. The second semiconductor chip 120B and the fourth semiconductor chip 120D may be each connected to the substrate 110 through the first semiconductor chip 120A and the third semiconductor chip 120C, respectively.

In addition to the above description, a description of another portion of the present specification may be equally applied to descriptions of other components unless there is a particularly contradictory description.

Each of FIG. 8 and FIG. 9 is a cross-sectional view of a semiconductor package according to another embodiment.

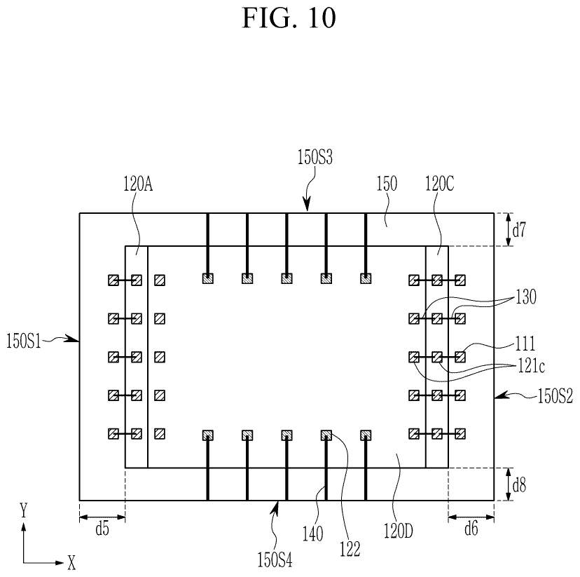

FIG. 10 is a plan view of the semiconductor package of FIG. 8.

Compared with the semiconductor package 100B, heat dissipation wires 140 of the semiconductor package 100C may be each exposed to a third side surface 150S3 and a fourth side surface 150S4 of an encapsulant 150.

The third side surface 150S3 and the fourth side surface 150S4 of the encapsulant 150 may be side surfaces having a narrow interval with semiconductor chips 120A, 120B, 120C, and 120D. That is, a distance d7 from the third side surface 150S3 of the encapsulant 150 to the semiconductor chips 120A, 120B, 120C, and 120D and a distance d8 from the fourth side surface 150S4 of the encapsulant 150 to the semiconductor chips 120A, 120B, 120C, and 120D may be lower than a distance d5 from a first side surface 150S1 of the encapsulant 150 to the semiconductor chips 120A, 120B, 120C, and 120D and a distance d6 from a second side surface 150S2 of the encapsulant 150 to the semiconductor chips 120A, 120B, 120C, and 120D.

Because each of the heat dissipation wires 140 is exposed to a side surface of the encapsulant 150 having a narrow interval with the semiconductor chip 120, a heat dissipation path may be shortened and heat accumulation in the encapsulant 150 may be reduced so that a heat dissipation characteristic of the semiconductor package is further improved. In addition, a narrow space that is difficult to use for a separate use of the semiconductor package may be utilized as a heat dissipation path. In addition, because the heat dissipation wires 140 extend in the Y direction (Y) between a bonding wire 130 extending toward the first side surface 150S1 of the encapsulant 150 and the bonding wire 130 extending toward the second side surface 150S2, the heat dissipation characteristic of the semiconductor package may be improved without affecting a disposition space of bonding wires 130.

In addition to the above description, a description of another portion of the present specification may be equally applied to descriptions of other components unless there is a particularly contradictory description.

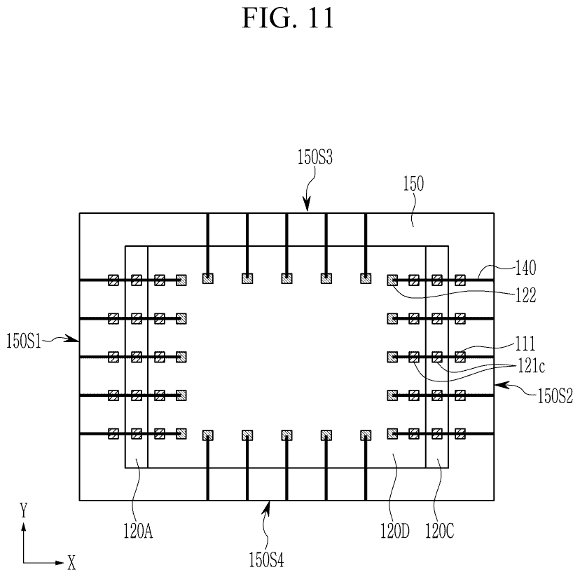

FIG. 11 is a plan view according to a modified example of the semiconductor package of FIG. 7.

The heat dissipation wires 140 may further include a heat dissipation wire exposed to the third side surface 150S3 of the encapsulant 150 and a heat dissipation wire exposed to the fourth side surface 150S4 of the encapsulant 150.

If the semiconductor package includes the heat dissipation wires 140 exposed to four side surfaces 150S1, 150S2, 150S3, and 150S4 of the encapsulant 150, the semiconductor package may have a better heat dissipation characteristic.

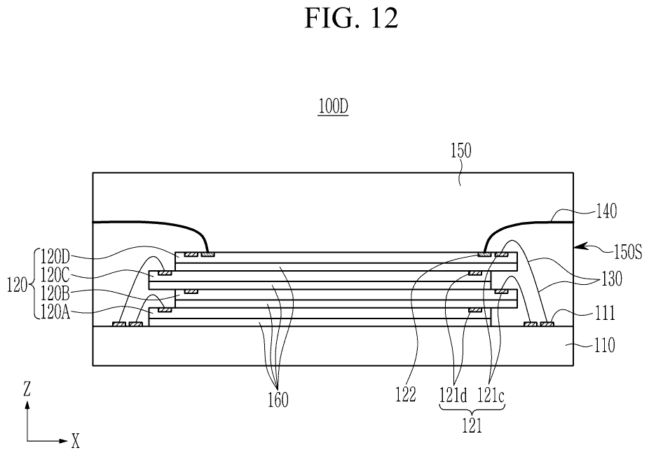

FIG. 12 is a cross-sectional view of a semiconductor package according to another embodiment.

Compared with the semiconductor package 100B, bonding wires 130 of the semiconductor package 100D may extend from each of semiconductor chips 120A, 120B, 120C, and 120D to a substrate 110. That is, the semiconductor chips 120A, 120B, 120C, and 120D may be connected to the substrate 110 without passing through other semiconductor chips.

For example, the bonding wires 130 may include a bonding wire connecting the first semiconductor chip 120A to the substrate 110, a bonding wire connecting the second semiconductor chip 120B to the substrate 110, a bonding wire connecting the third semiconductor chip 120C to the substrate 110, and a bonding wire connecting the fourth semiconductor chip 120D to the substrate 110.

In addition to the above description, a description of another portion of the present specification may be equally applied to descriptions of other components unless there is a particularly contradictory description.

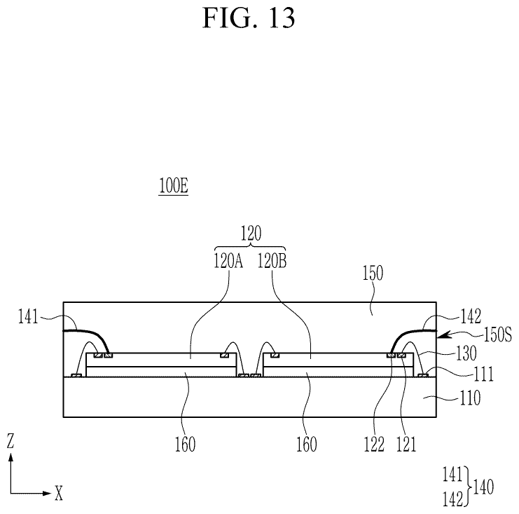

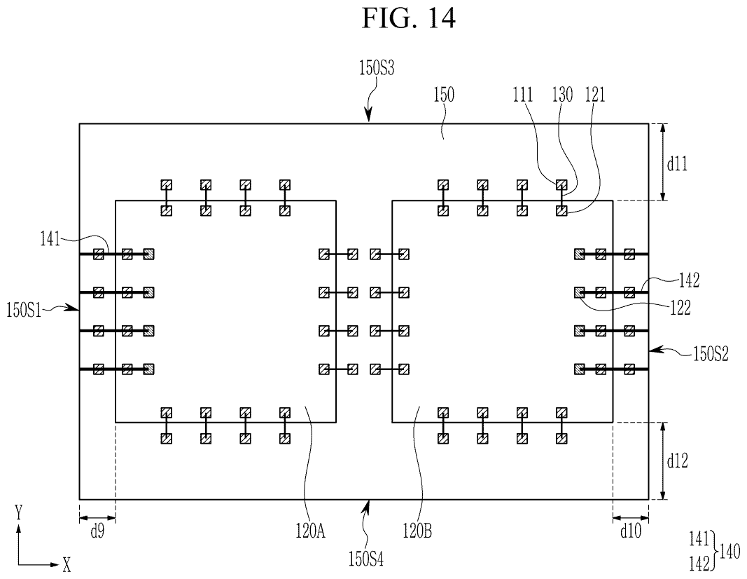

FIG. 13 is a cross-sectional view of a semiconductor package according to another embodiment.

FIG. 14 is a plan view of the semiconductor package of FIG. 13.

A semiconductor chip 120 of the semiconductor package 100E may include a plurality of semiconductor chips spaced apart from each other above a substrate 110. For example, semiconductor chips 120 may include a first semiconductor chip 120A and a second semiconductor chip 120B spaced apart from the first semiconductor chip 120A in the X direction (X). Each of the first semiconductor chip 120A and the second semiconductor chip 120B may be connected to the substrate 110 by a bonding wire 130.

Heat dissipation wires 140 may include at least one first heat dissipation wire 141 connected to the first semiconductor chip 120A and at least one second heat dissipation wire 142 connected to the second semiconductor chip 120B.

In an embodiment, the first heat dissipation wire 141 and the second heat dissipation wire 142 may be exposed to different side surfaces 150S of an encapsulant 150. For example, the first heat dissipation wire 141 may be exposed to a first side surface 150S1, and the second heat dissipation wire 142 may be exposed to a second side surface 150S2. The first heat dissipation wire 141 and the second heat dissipation wire 142 may be spaced apart from each other in the X direction (X). Each of first heat dissipation wires 141 and second heat dissipation wires 142 may be disposed along the Y direction (Y). However, according to an embodiment, each of the first heat dissipation wire 141 and the second heat dissipation wire 142 may be exposed to the same side surface 150S of the encapsulant 150.

A distance d9 from the first side surface 150S1 of the encapsulant 150 to the first semiconductor chip 120A and a distance d10 from the second side surface 150S2 of the encapsulant 150 to the second semiconductor chip 120B may be lower than a distance d11 from a third side surface 150S3 of the encapsulant 150 to the semiconductor chips 120A and 120B and a distance d12 from a fourth side surface 150S4 of the encapsulant 150 to the semiconductor chips 120A and 120B.

In addition to the above description, a description of another portion of the present specification may be equally applied to descriptions of other components unless there is a particularly contradictory description.

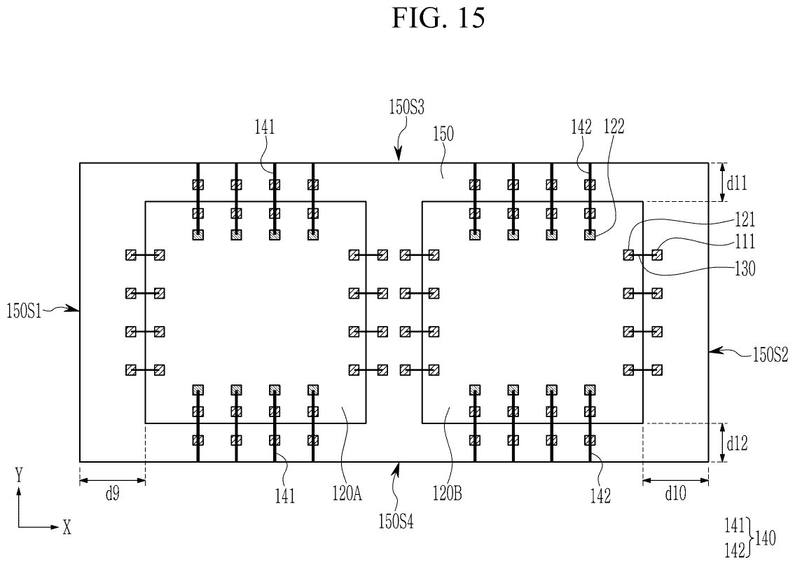

FIG. 15 is a plan view according to a modified example of the semiconductor package of FIG. 13.

Compared with the semiconductor package 100E, first heat dissipation wires 141 connected to the first semiconductor chip 120A may include a heat dissipation wire exposed to the third side surface 150S3 of the encapsulant 150 and a heat dissipation wire exposed to the fourth side surface 150S4. Second heat dissipation wires 142 connected to the second semiconductor chip 120B may include a heat dissipation wire exposed to the third side surface 150S3 of the encapsulant 150 and a heat dissipation wire exposed to the fourth side surface 150S4.

To improve a heat dissipation characteristic, a distance d11 from the third side surface 150S3 of the encapsulant 150 to the semiconductor chips 120A and 120B and a distance d12 from the fourth side surface 150S4 of the encapsulant 150 to the semiconductor chips 120A and 120B may be designed to be lower than a distance d9 from the first side surface 150S1 to the first semiconductor chip 120A and a distance d10 from the second side surface 150S2 of the encapsulant 150 to the second semiconductor chip 120B.

In addition to the above description, a description of another portion of the present specification may be equally applied to descriptions of other components unless there is a particularly contradictory description.

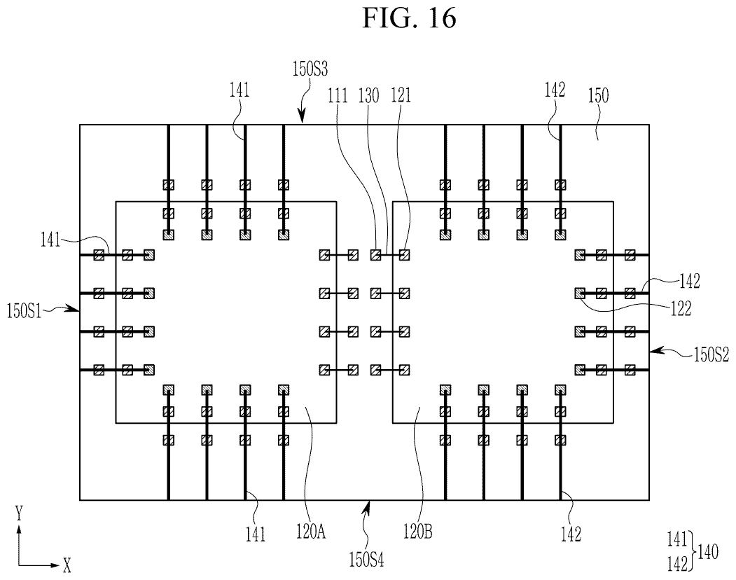

FIG. 16 is a plan view according to another modified example of the semiconductor package of FIG. 13.

Compared with the semiconductor package 100E, first heat dissipation wires 141 connected to the first semiconductor chip 120A may further include a heat dissipation wire exposed to the third side surface 150S3 and a heat dissipation wire exposed to the fourth side surface 150S4. Second heat dissipation wires 142 connected to the second semiconductor chip 120B may further include a heat dissipation wire exposed to the third side surface 150S3 and a heat dissipation wire exposed to the fourth side surface 150S4.

If the semiconductor package includes heat dissipation wires 140 exposed to four side surfaces 150S1, 150S2, 150S3, and 150S4 of the encapsulant 150, the semiconductor package may have a better heat dissipation characteristic.

In addition to the above description, a description of another portion of the present specification may be equally applied to descriptions of other components unless there is a particularly contradictory description.

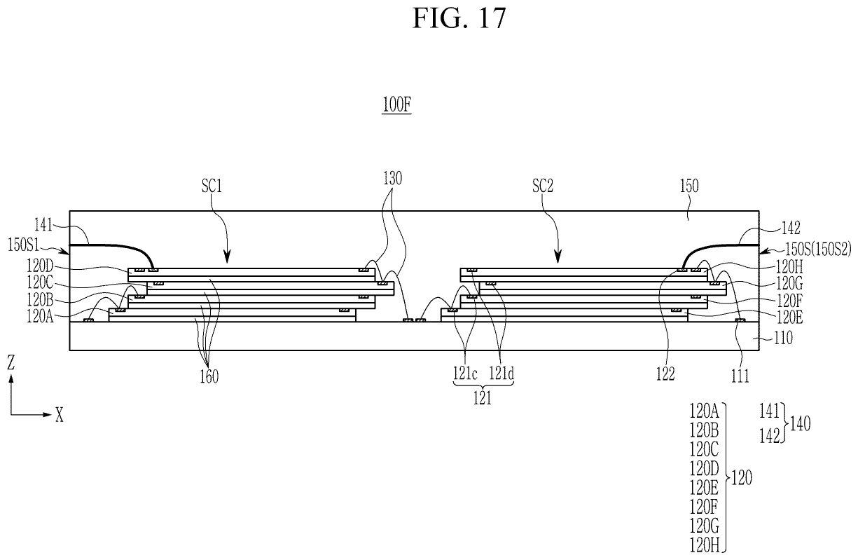

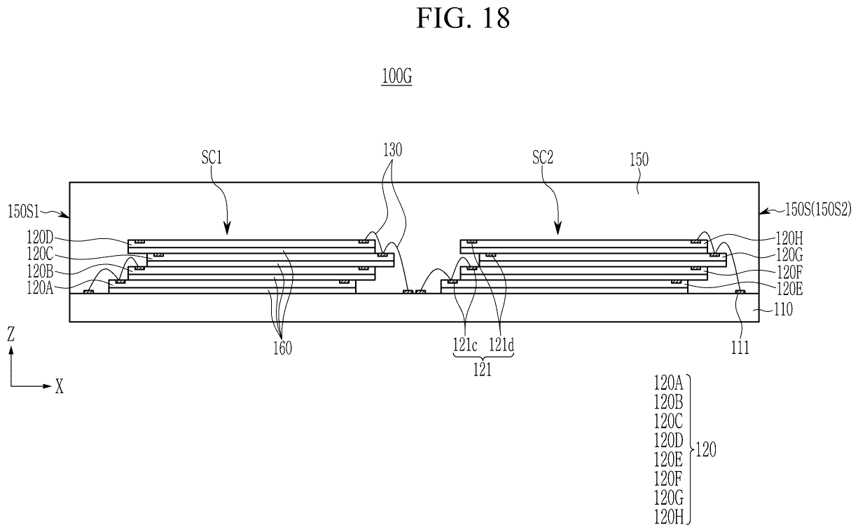

FIG. 17 is a cross-sectional view of a semiconductor package according to another embodiment.

The semiconductor package 100F may include each of a plurality of stacked chip structures SC1 and SC2 including a plurality of semiconductor chips 120 and spaced apart from each other. For example, the semiconductor package 100F may include the first stacked chip structure SC1 including a first semiconductor chip 120A, a second semiconductor chip 120B, a third semiconductor chip 120C, and a fourth semiconductor chip 120D, and a second stacked chip structure SC2 spaced apart from the first stacked chip structure SC1 in the X direction (X) and including a fifth semiconductor chip 120E, a sixth semiconductor chip 120F, a seventh semiconductor chip 120G, and an eighth semiconductor chip 120H.

Heat dissipation wires 140 may include at least one first heat dissipation wire 141 connected to the first stacked chip structure SC1 and at least one second heat dissipation wire 142 connected to the second stacked chip structure SC2.

The first heat dissipation wire 141 may be connected to at least one of the semiconductor chips 120A, 120B, 120C, and 120D of the first stacked chip structure SC1 (e.g., an uppermost semiconductor chip 120D). The second heat dissipation wire 142 may be connected to at least one of the semiconductor chips 120E, 120F, 120G, and 120H of the second stacked chip structure SC2 (e.g., an uppermost semiconductor chip 120H).

In an embodiment, the first heat dissipation wire 141 and the second heat dissipation wire 142 may be each exposed to different side surfaces 150S of the encapsulant 150. For example, the first heat dissipation wire 141 may be exposed to a first side surface 150S1, and the second heat dissipation wire 142 may be exposed to a second side surface 150S2. The first heat dissipation wire 141 and the second heat dissipation wire 142 may be spaced apart from each other in the X direction (X).

In addition to the above description, a description of another portion of the present specification may be equally applied to descriptions of other components unless there is a particularly contradictory description.

Each of FIG. 18 and FIG. 19 is a cross-sectional view of a semiconductor package according to another embodiment.

Compared with the semiconductor package 100F, a first heat dissipation wire 141 of the semiconductor package 100G may be exposed to a third side surface 150S3, and a second heat dissipation wire 142 of the semiconductor package 100G may be exposed to a fourth side surface 150S4. The first heat dissipation wire 141 and the second heat dissipation wire 142 may be spaced apart from each other in the Y direction (Y).

In addition to the above description, a description of another portion of the present specification may be equally applied to descriptions of other components unless there is a particularly contradictory description.

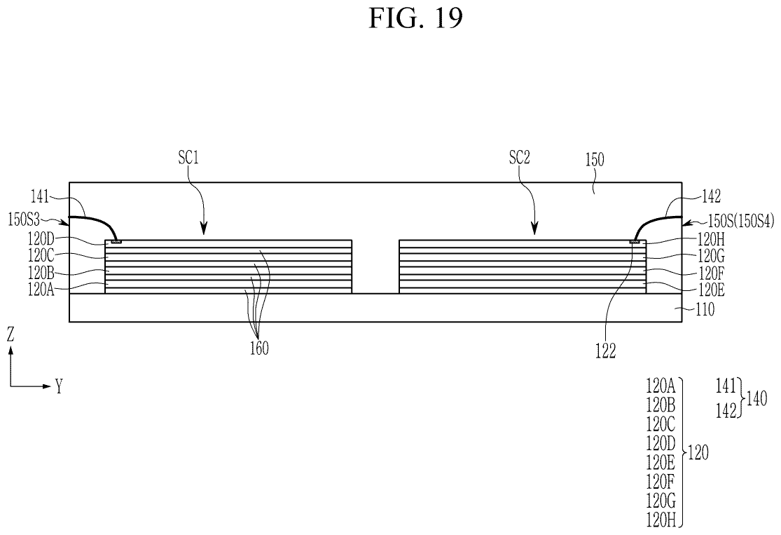

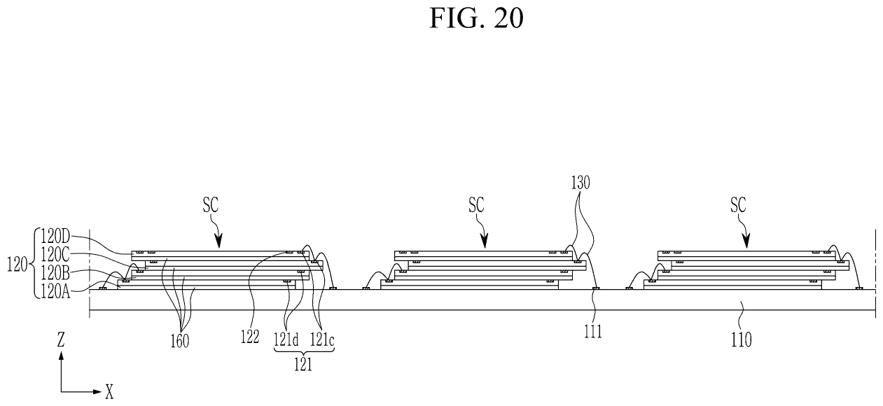

FIGS. 20 to 24 are manufacturing process views of the semiconductor package of FIG. 6.

First, referring to FIG. 20, stacked chip structures SC in which the first semiconductor chip 120A, the second semiconductor chip 120B, the third semiconductor chip 120C, and the fourth semiconductor chip 120D are stacked above the substrate 110 may be disposed to be spaced apart from each other. The stacked chip structure SC may be formed above the substrate 110 by sequentially stacking the first semiconductor chip 120A, the second semiconductor chip 120B, the third semiconductor chip 120C, and the fourth semiconductor chip 120D above the substrate 110, or may be formed above the substrate 110 by separately forming the first semiconductor chip 120A, the second semiconductor chip 120B, the third semiconductor chip 120C, and the fourth semiconductor chip 120D above the substrate 110.

Semiconductor chips 120 of the stacked chip structure SC and the substrate 110 may be connected by bonding wires 130. One end of the bonding wire 130 may be connected to the connection pad 121c of the semiconductor chip 120, and the other end of the bonding wire 130 may be connected to the pad 111 of the substrate 110 or the connection pad 121c of another semiconductor chip 120.

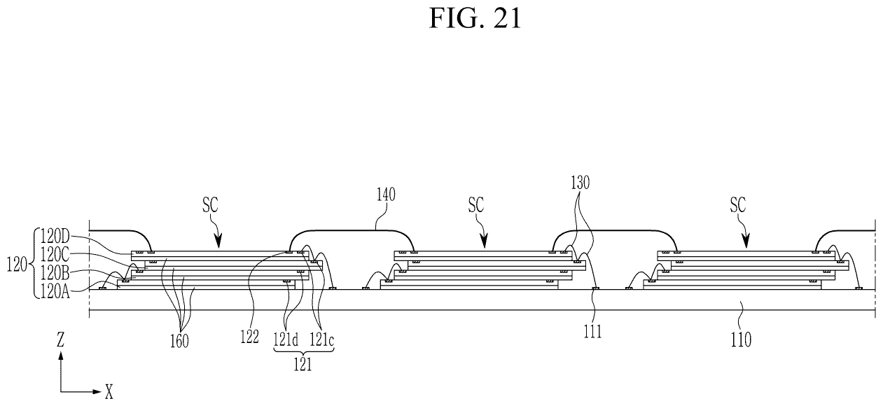

Next, referring to FIG. 21, the stacked chip structures SC adjacent to each other may be connected by the heat dissipation wire 140. For example, the heat dissipation wire 140 may connect uppermost semiconductor chips 120D of the stacked chip structures SC adjacent to each other. One end and the other end of the heat dissipation wire 140 may be each connected to heat dissipation pads 122 of stacked chip structures SC adjacent to each other.

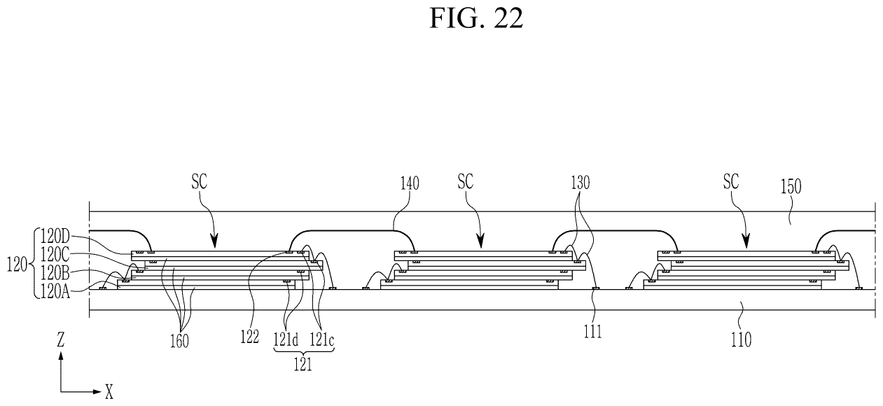

Next, referring to FIG. 22, a semiconductor package in a state before cutting may be formed by forming the encapsulant 150 that seals the stacked chip structures SCs, the bonding wires 130, and heat dissipation wires 140. The encapsulant 150 may be formed by a known method such as compression molding or transfer molding.

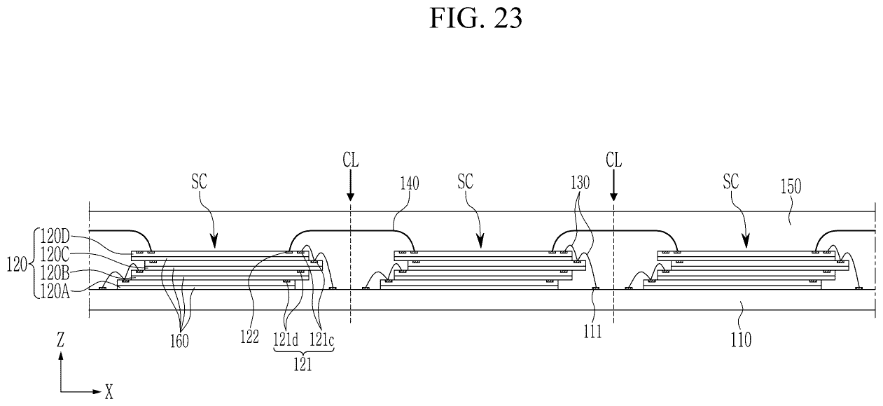

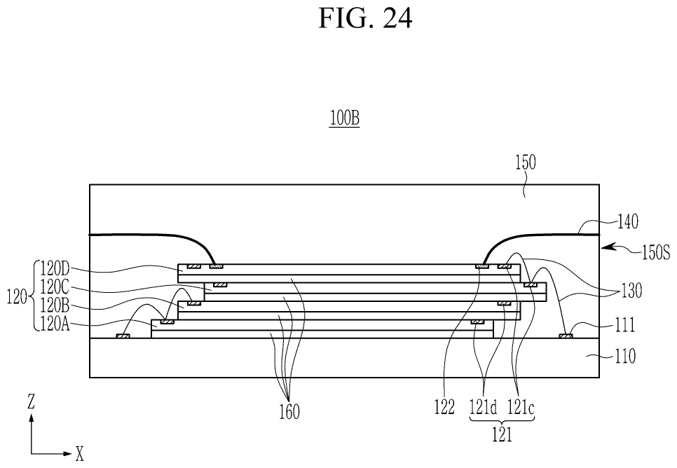

Finally, referring to FIG. 23 and FIG. 24, individual semiconductor packages 100B may be separated by cutting along a cutting line CL between the stacked chip structures SC. For example, the cutting may be performed by laser processing, blade processing, or a combination thereof. In the cutting process, the heat dissipation wires 140 may be cut together with the encapsulant 150 so that the heat dissipation wires are exposed to the side surface 150S of the encapsulant 150.

While this disclosure has been described in connection with what is presently considered to be practical embodiments, it should be understood that the disclosure is not limited to the disclosed embodiments, but is intended to cover various modifications and equivalent arrangements included within the spirit and scope of the appended claims.

In addition, the embodiments of the present disclosure are not independent of each other and may be implemented in combination with each other unless otherwise contradictory. Accordingly, the combined embodiments should also be considered to be included in the present disclosure.

What is claimed is:

1. A semiconductor package comprising:
a substrate;
a semiconductor chip on the substrate and electrically connected to the substrate;
at least one heat dissipation wire connected to the semiconductor chip; and
an encapsulant on at least a portion of each of the semiconductor chip and the heat dissipation wire,
wherein the heat dissipation wire is exposed to one side surface of side surfaces of the encapsulant.

2. The semiconductor package of claim 1, wherein the side surfaces of the encapsulant comprise a first side surface and a second side surface facing each other and a third side surface and a fourth side surface connecting the first side surface and the second side surface and facing each other, and wherein the heat dissipation wire comprises a first heat dissipation wire penetrating the first side surface of the encapsulant and a second heat dissipation wire penetrating the second side surface of the encapsulant.

3. The semiconductor package of claim 2, wherein a distance between each of the first side surface and the second side surface and the semiconductor chip is less than a distance between each of the third side surface and the fourth side surface and the semiconductor chip.

4. The semiconductor package of claim 2, wherein the heat dissipation wire further comprises a third heat dissipation wire penetrating the third side surface of the encapsulant and a fourth heat dissipation wire penetrating the fourth side surface of the encapsulant.

5. The semiconductor package of claim 1, further comprising at least one bonding wire electrically connecting the semiconductor chip and the substrate.

6. The semiconductor package of claim 5, wherein a diameter of the heat dissipation wire is greater than or equal to a diameter of the bonding wire.

7. The semiconductor package of claim 5, wherein the semiconductor chip comprises a connection pad and a heat dissipation pad on a first surface, the bonding wire electrically connected to the connection pad, and the heat dissipation wire connected to the heat dissipation pad.

8. The semiconductor package of claim 7, wherein a second surface opposite the first surface of the semiconductor chip faces the substrate.

9. The semiconductor package of claim 8, further comprising an adhesive member between the semiconductor chip and the substrate.

10. A semiconductor package comprising:
a substrate;
a plurality of semiconductor chips on the substrate;
bonding wires electrically connecting each of the plurality of semiconductor chips to the substrate;
at least one heat dissipation wire connected to at least one of the plurality of semiconductor chips; and
an encapsulant on at least a portion of each of the plurality of semiconductor chips, the bonding wires, and the heat dissipation wire,
wherein the heat dissipation wire is exposed to one side surface of side surfaces of the encapsulant.

11. The semiconductor package of claim 10, wherein the heat dissipation wire comprises a heat dissipation wire connected to an uppermost semiconductor chip among the plurality of semiconductor chips.

12. The semiconductor package of claim 10, wherein the side surfaces of the encapsulant comprise a first side surface and a second side surface facing each other and a third side surface and a fourth side surface connecting the first side surface and the second side surface and facing each other, the heat dissipation wire comprising a first heat dissipation wire penetrating the first side surface of the encapsulant and a second heat dissipation wire penetrating the second side surface of the encapsulant, the bonding wires comprising a first bonding wire electrically connected to the substrate and between the first side surface of the encapsulant and the plurality of semiconductor chips and a second bonding wire electrically connected to the substrate and between the second side surface of the encapsulant and the plurality of semiconductor chips.

13. The semiconductor package of claim 12, wherein the heat dissipation wire further comprises a third heat dissipation wire penetrating the third side surface of the encapsulant and a fourth heat dissipation wire penetrating the fourth side surface of the encapsulant.

14. The semiconductor package of claim 10, wherein the side surfaces of the encapsulant comprise a first side surface and a second side surface facing each other and a third side surface and a fourth side surface connecting the first side surface and the second side surface and facing each other, the heat dissipation wire comprising a first heat dissipation wire penetrating the third side surface of the encapsulant and a second heat dissipation wire penetrating the fourth side surface of the encapsulant, and the bonding wires comprising a first bonding wire electrically connected to the substrate and between the first side surface of the encapsulant and the plurality of semiconductor chips and a second bonding wire electrically connected to the substrate and between the second side surface of the encapsulant and the plurality of semiconductor chips.

15. The semiconductor package of claim 10, wherein the bonding wires comprise a bonding wire electrically connecting one semiconductor chip of the plurality of semiconductor chips to another semiconductor chip of the plurality of semiconductor chips.

16. The semiconductor package of claim 10, wherein each of the bonding wires extends from a corresponding semiconductor chip of the plurality of semiconductor chips to the substrate.

17. A semiconductor package comprising:
a substrate;
a first semiconductor chip on the substrate;
a second semiconductor chip spaced apart from the first semiconductor chip and on the substrate;
first bonding wires that electrically connect the first semiconductor chip and the substrate;
second bonding wires that electrically connect the second semiconductor chip and the substrate;
a first heat dissipation wire connected to the first semiconductor chip;
a second heat dissipation wire connected to the second semiconductor chip; and
an encapsulant on at least a portion of each of the first and second semiconductor chips, the first bonding wires, the second bonding wires, the first heat dissipation wire, and the second heat dissipation wire,
wherein each of the first heat dissipation wire and the second heat dissipation wire is exposed to one side surface of side surfaces of the encapsulant.

18. The semiconductor package of claim 17, wherein the side surfaces of the encapsulant comprise a first side surface and a second side surface facing each other and a third side surface and a fourth side surface connecting the first side surface and the second side surface and facing each other, the first semiconductor chip and the second semiconductor chip are spaced apart from each other in a direction from the first side surface of the encapsulant to the second side surface of the encapsulant, and the first heat dissipation wire is exposed to the first side surface of the encapsulant and the second heat dissipation wire is exposed to the second side surface of the encapsulant.

19. The semiconductor package of claim 18, further comprising:
a third heat dissipation wire connected to the first semiconductor chip and exposed to the third side surface of the encapsulant;
a fourth heat dissipation wire connected to the second semiconductor chip and exposed to the third side surface of the encapsulant;
a fifth heat dissipation wire connected to the first semiconductor chip and exposed to the fourth side surface of the encapsulant; and
a sixth heat dissipation wire connected to the second semiconductor chip and exposed to the fourth side surface of the encapsulant.

20. The semiconductor package of claim 17, wherein the side surfaces of the encapsulant comprise a first side surface and a second side surface facing each other and a third side surface and a fourth side surface connecting the first side surface and the second side surface and facing each other, the first semiconductor chip and the second semiconductor chip are spaced apart from each other in a direction from the first side surface of the encapsulant to the second side surface of the encapsulant, the first heat dissipation wire and the second heat dissipation wire are exposed to the third side surface of the encapsulant, and the semiconductor package further comprises a third heat dissipation wire connected to the first semiconductor chip and penetrating the fourth side surface of the encapsulant and a fourth heat dissipation wire connected to the second semiconductor chip and penetrating the fourth side surface of the encapsulant.
